(19) United States
(12) Patent Application Publication
(10) Pub. No.: US 2016/0247846 A1
(43) Pub. Date: Aug. 25, 2016

(54) PHOTOELECTRIC CONVERSION APPARATUS

(71) Applicant: CANON KABUSHIKI KAISHA, Tokyo (JP)

(72) Inventors: Satoko Iida, Yokohama-shi (JP); Toru Koizumi, Yokohama-shi (JP); Tatsuya Suzuki, Yokohama-shi (JP); Jun Iba, Yokohama-shi (JP)

(21) Appl. No.: 15/003,956

(22) Filed: Jan. 22, 2016

(30) Foreign Application Priority Data
Feb. 19, 2015 (JP) 2015-030289

(51) Int. Cl. H01L 27/146

(52) U.S. Cl. CPC H01L 27/14607; H01L 27/14643; H01L 27/14612

(57) ABSTRACT

Provided is a photoelectric conversion apparatus including a photoelectric conversion element. The photoelectric conversion element includes a first semiconductor region, a second semiconductor region, and a third semiconductor region. The second semiconductor region has a shape in plan view including a base portion containing a third semiconductor region in plan view and a first protrusion and a second protrusion each connected to the base portion. When an axial length of the first protrusion is defined as L1, a distance from a connected portion between the first protrusion and the base portion to the third semiconductor region is defined as L2, an axial length of the second protrusion is defined as L3, and a distance from a connected portion between the second protrusion and the base portion to the third semiconductor region is defined as L4, relationships of L1>L3 and L2<L4 are satisfied.

### BACKGROUND OF THE INVENTION

1. Field of the Invention

The present invention relates to a photoelectric conversion apparatus.

2. Description of the Related Art

A photoelectric conversion element is required to realize high-sensitivity and high-speed reading. As a measure for enlarging the area of a photo-receiving unit for the purpose of increasing sensitivity and reading a charge within a predetermined read time, a photo-receiving unit structure has been proposed in Japanese Patent Application Laid-Open No. 2012-19056.

In Japanese Patent Application Laid-Open No. 2012-19056, there is a disclosure that a charge collection speed is increased by forming an inner region having a cross shape in a photo-receiving unit.

However, there is a demand for a further increase in charge collection speed in order to further increase sensitivity of a photoelectric conversion apparatus.

### SUMMARY OF THE INVENTION

According to one embodiment of the present invention, there is provided a photoelectric conversion apparatus, including: a photoelectric conversion element including: a first semiconductor region of a first conductivity type formed in a semiconductor substrate; a second semiconductor region of a second conductivity type formed in the semiconductor substrate, the first semiconductor region and the second semiconductor region forming a PN junction; and a third semiconductor region of a second conductivity type formed in contact with a surface of the semiconductor substrate and in contact with the second semiconductor region; and a read circuit electrically connected to the third semiconductor region, the read circuit being configured to read a charge generated by the photoelectric conversion element, in which the second semiconductor region has a shape in plan view including: a base portion containing the third semiconductor region in the plan view; and a first protrusion and a second protrusion, each being connected to the base portion and having a width that becomes small from a side connected to the base portion toward a tip end, and in which, when a first distance from the tip end of the first protrusion to a connected portion between the first protrusion and the base portion in the plan view is defined as L1, a second distance from the connected portion between the first protrusion and the base portion to the third semiconductor region in the plan view is defined as L2, a third distance from the tip end of the second protrusion to a connected portion between the second protrusion and the base portion in the plan view is defined as L3, and a fourth distance from the connected portion between the second protrusion and the base portion to the third semiconductor region in the plan view is defined as L4, relationships of L1>L3 and L2<L4 are satisfied.

Further features of the present invention will become apparent from the following description of exemplary embodiments with reference to the attached drawings.

### BRIEF DESCRIPTION OF THE DRAWINGS

FIG. 1 is a circuit diagram for illustrating a read circuit and a reset circuit of a photoelectric conversion apparatus according to a first embodiment of the present invention.

FIG. 2 is a view for illustrating a planar layout, a sectional structure, and a potential distribution of a photodiode in the photoelectric conversion apparatus according to the first embodiment of the present invention.

FIG. 3 is a view for illustrating a sectional structure and a potential distribution of the photodiode in the photoelectric conversion apparatus according to the first embodiment of the present invention in a cross-section different from those of FIG. 2.

FIG. 4 is a view for illustrating a planar layout, a sectional structure, and a potential distribution of a photodiode in a photoelectric conversion apparatus according to a second embodiment of the present invention.

FIG. 5 is a view for illustrating a sectional structure and a potential distribution of the photodiode in the photoelectric conversion apparatus according to the second embodiment of the present invention in a cross-section different from those of FIG. 4.

FIG. 6A, FIG. 6B, and FIG. 6C are each a view for illustrating a planar layout of a photodiode in a photoelectric conversion apparatus according to a modified example of the second embodiment of the present invention.

FIG. 7 is a circuit diagram for illustrating a read circuit and a reset circuit of a photoelectric conversion apparatus according to a third embodiment of the present invention.

FIG. 8 is a view for illustrating a planar layout of a photodiode in the photoelectric conversion apparatus according to the third embodiment of the present invention.

FIG. 9 is view for illustrating a planar layout, a sectional structure, and a potential distribution of a photodiode in a photoelectric conversion apparatus according to a fourth embodiment of the present invention.

FIG. 10 is a view for illustrating a planar layout, a sectional structure, and a potential distribution of a photodiode in a photoelectric conversion apparatus according to a fifth embodiment of the present invention.

FIG. 11 is a schematic diagram for illustrating a configuration of an imaging system according to a sixth embodiment of the present invention.

### DESCRIPTION OF THE EMBODIMENTS

Preferred embodiments of the present invention will now be described in detail in accordance with the accompanying drawings.

Some of the embodiments of the present invention can be applied to photoelectric conversion apparatus including a plurality of pixels, such as a CCD image sensor and a CMOS image sensor. In particular, some of the embodiments are effectively applied to a photoelectric conversion apparatus including pixels in which the size of a photo-receiving unit is relatively large (for example, one side of the photo-receiving unit is 10 μm or more). Further, some of the embodiments can also be applied to a structure involving the movement of a charge in a lower portion of a light-shielding layer that does not receive light, for example, a structure involving the charge transfer of a CCD, the charge transport in a memory unit of an electronic shutter, or the like.

Now, photoelectric conversion apparatus according to embodiments of the present invention are described with reference to the drawings. In the following embodiments, the case where a signal charge generated by a photoelectric conversion element is a hole is described. In this case, a first conductivity type corresponds to a P-type, and a second conductivity type corresponds to an N-type. Note that, the signal charge generated by the photoelectric conversion element may be an electron. In the case where the signal charge is an electron, the first conductivity type corresponds to an N-type, and the second conductivity type corresponds to a P-type.

### First Embodiment

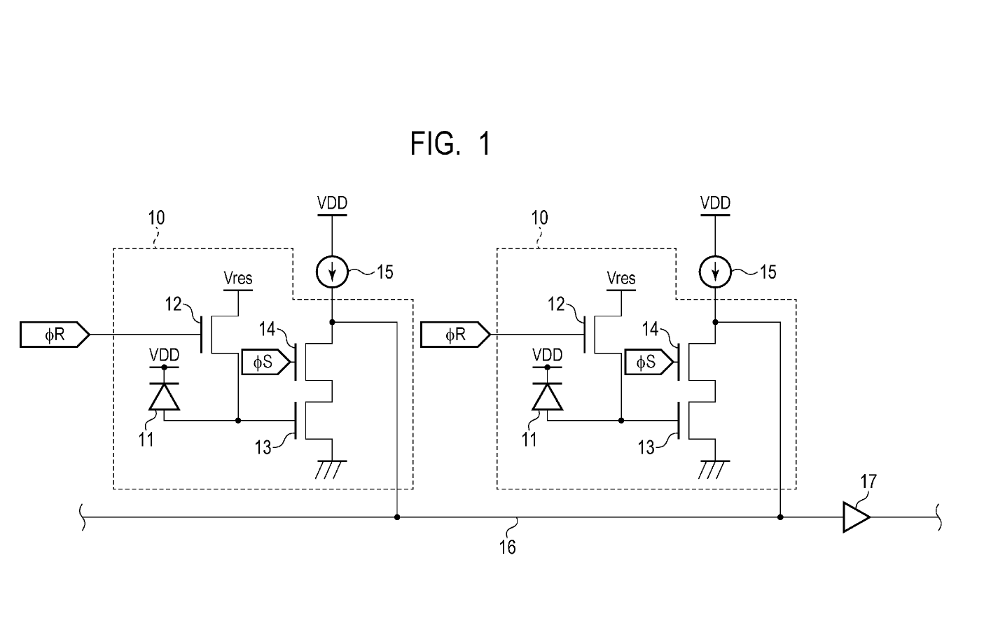

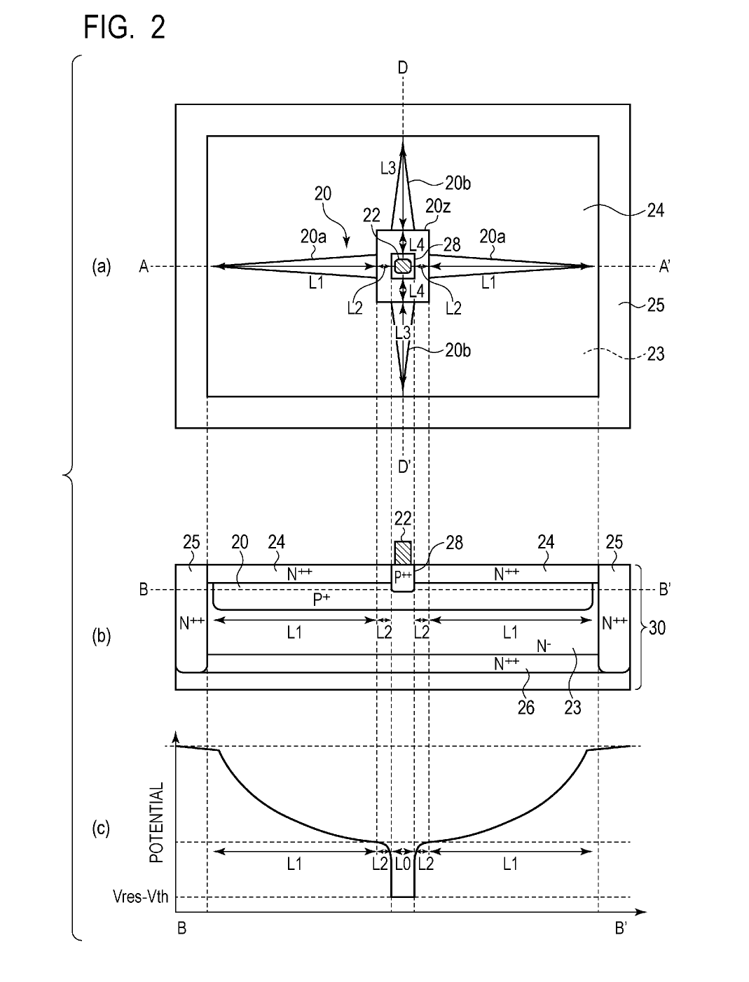

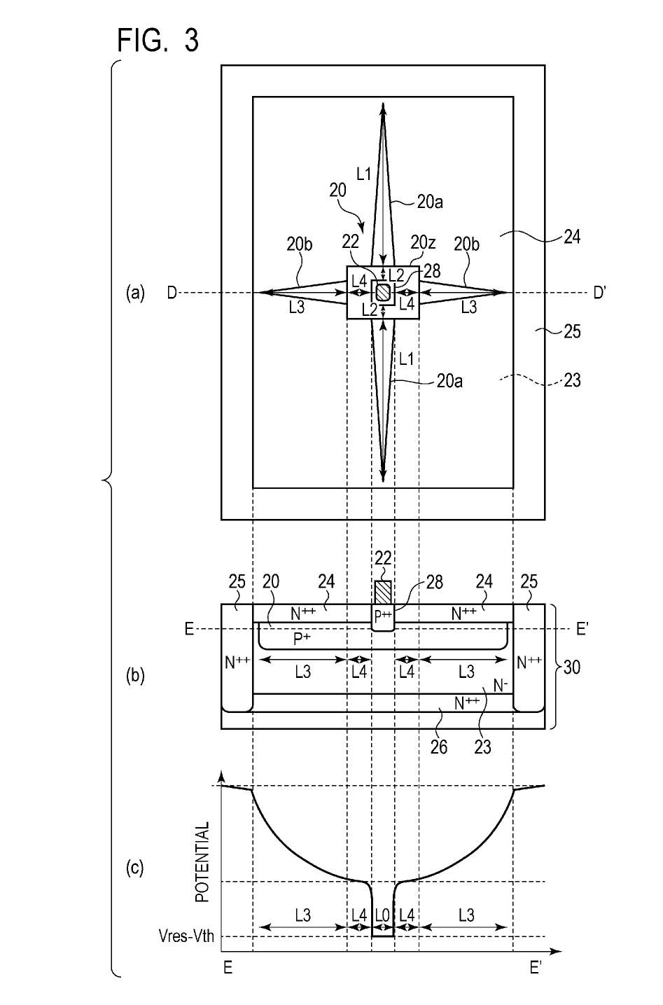

A photoelectric conversion apparatus according to a first embodiment of the present invention is described with reference to FIG. 1, FIG. 2, and FIG. 3. FIG. 1 is a circuit diagram for illustrating a read circuit and a reset circuit of the photoelectric conversion apparatus according to this embodiment. FIG. 2 is a view for illustrating a planar layout, a sectional structure, and a potential distribution of a photodiode in the photoelectric conversion apparatus according to this embodiment. FIG. 3 is a view for illustrating a sectional structure and a potential distribution of the photodiode in the photoelectric conversion apparatus according to this embodiment in a cross-section different from those of FIG. 2.

First, a schematic configuration of a pixel region in the photoelectric conversion apparatus according to this embodiment is described with reference to FIG. 1 and FIG. 2.

The photoelectric conversion apparatus according to this embodiment includes a plurality of unit pixels 10 in a pixel region. In FIG. 1, two unit pixels 10 arranged in a row direction (horizontal direction of the figure) are illustrated, but the number of the unit pixels 10 arranged in the row direction is not limited thereto. Further, the unit pixels 10 may be arranged in a column direction (vertical direction of the figure) or may be arranged in an array in the row direction and the column direction. Further, the photoelectric conversion apparatus does not necessarily required to include a plurality of unit pixels and may have a configuration including only one unit pixel 10.

Each of the unit pixels 10 includes a photodiode 11 serving as a photoelectric conversion element and an in-pixel read circuit for reading a signal charge from the photodiode 11. The in-pixel read circuit includes a reset MOS transistor 12, an amplification MOS transistor 13, and a select MOS transistor 14. Note that, each MOS transistor may be formed of any one of a PMOS and an NMOS, and a drain and a source serving as main electrodes of each transistor may be reversed from those described herein depending on a voltage to be input.

A cathode of the photodiode 11 is connected to a power-supply voltage line (voltage VDD), and an anode thereof is connected to a source of the reset MOS transistor 12 and a gate of the amplification MOS transistor 13. A drain of the reset MOS transistor 12 is connected to a reset voltage line (voltage Vres). A drain of the amplification MOS transistor 13 is grounded, and a source thereof is connected to a drain of the select MOS transistor 14. A source of the select MOS transistor 14 is connected to the power-supply voltage line (voltage VDD) through intermediation of a constant current source 15. A gate of the reset MOS transistor 12 is connected to a reset signal line (not illustrated) so that the operation of the reset MOS transistor 12 can be controlled with a reset signal φR. Further, a gate of the select MOS transistor 14 is connected to a select signal line (not illustrated) so that the operation of the select MOS transistor 14 can be controlled with a select signal φS. Sources of the select MOS transistors 14 of the plurality of unit pixels 10 belonging to the same row are connected to a signal read line 16. The signal read line 16 is connected to an output buffer 17 forming a part of a signal read circuit.

A specific configuration of the photodiode 11 in the photoelectric conversion apparatus according to this embodiment is described with reference to FIG. 2. FIG. 2(a) is a plan view for illustrating a planar layout of the photodiode 11. FIG. 2(b) is a sectional view taken along the line A-A′ of FIG. 2(a). FIG. 2(c) is a view for illustrating a potential distribution of a portion along the line B-B′ of FIG. 2(b).

First, a sectional structure of the photodiode 11 formed in a semiconductor substrate 30 is described with reference to FIG. 2(b). As illustrated in FIG. 2(b), in the semiconductor substrate 30, an N⁻-type semiconductor region 23, N⁺⁺-type semiconductor regions 24, 25, and 26, a P⁺-type semiconductor region 20, and a P⁺⁺-type semiconductor region 28 are formed. An electrode 22 is formed on the P⁺⁺-type semiconductor region 28.

The N⁻-type semiconductor region 23 is a semiconductor region (first semiconductor region) forming a well. As illustrated in FIG. 2(a) and FIG. 2(b), the N⁺⁺-type semiconductor region 25 is arranged on a side portion of the N⁻-type semiconductor region 23. Further, as illustrated in FIG. 2(b), the N⁺⁺-type semiconductor region is arranged on a bottom portion of the N⁻-type semiconductor region 23. With this, the periphery of the N⁻-type semiconductor region 23 is surrounded by the N⁺⁺-type semiconductor region 25 and the N⁺⁺-type semiconductor region 26. The N⁺⁺-type semiconductor region 25 serves as a barrier layer for preventing a signal charge in the N⁻-type semiconductor region 23 from flowing out to an adjacent element region. Further, the N⁺⁺-type semiconductor region 26 serves as a barrier layer for preventing a signal charge in the N⁻-type semiconductor region 23 from flowing out to a deep portion of the semiconductor substrate 30.

The N⁺⁺-type semiconductor region 24 is formed in a surface portion of the semiconductor substrate 30. The P⁺-type semiconductor region 20 (second semiconductor region) is formed on a bottom portion of the N⁺⁺-type semiconductor region 24. The P⁺⁺-type semiconductor region (third semiconductor region) connected to the P⁺-type semiconductor region 20 in a bottom portion thereof is formed in a part of the surface of the semiconductor substrate 30. The N⁻-type semiconductor region 23 and the P⁺-type semiconductor region 20 form a PN junction constructing the photodiode 11. The P⁺-type semiconductor region 20 also serves as an accumulation layer for accumulating a signal charge generated through photoelectric conversion. The N⁺⁺-type semiconductor region 24 serves as a dark current suppression region for suppressing a dark current by reducing the area of the PN junction in contact with the surface portion of the semiconductor substrate 30. The P⁺⁺-type semiconductor region 28 serves as a contact layer for ohmic-connecting the electrode 22 to the P⁺-type semiconductor region 20.

Next, the planar layout of the photodiode 11 is described with reference to FIG. 2(a). In the photodiode 11, a charge collection region in which the P⁺-type semiconductor region 20 is formed in plan view is formed. The P⁺-type semiconductor region 20 includes one base portion 20z, two protrusions 20a (first protrusions), and two protrusions 20b (second protrusions). The protrusions 20a and the protrusions 20b each have a triangular shape having a bottom side connected to the base portion 20z. The protrusion 20a has an axial length L1, and the protrusion 20b has an axial length L3. Further, the distance from the bottom side of the protrusion 20a to the P⁺⁺-type semiconductor region 28 is L2, and the distance from the bottom side of the protrusion 20b to the P⁺⁺-type semiconductor region 28 is L4. Herein, the axial length is defined as a distance (length of a line segment) from a tip end of each protrusion (apex of a triangle) to the center of the bottom side, that is, a connected portion with respect to the base portion 20z. In this embodiment, the axial length L3 is smaller than the axial length L1. In this embodiment, as illustrated in FIG. 2(a), two protrusions 20a and two protrusions 20b, that is, a total of four protrusions are arranged, and the respective protrusions have directions shifted by 90°. Note that, the shape of the protrusions 20a and the protrusions 20b is not necessarily a triangle, and it is sufficient that the protrusions 20a and the protrusions 20b each have a width that becomes smaller from the side connected to the base portion 20z toward the tip end.

The base portion 20z has a rectangular shape containing the P⁺⁺-type semiconductor region 28 in plan view. The length of each side of the base portion 20z is larger than the bottom side of the protrusion in contact with each side of the base portion 20z. The electrode 22 connected to the in-pixel read circuit is arranged on the surface of the semiconductor substrate 30 immediately above the P⁺⁺-type semiconductor region 28. Specifically, the P⁺⁺-type semiconductor region 28 is electrically connected to the in-pixel read circuit through the electrode 22. The P⁺-type semiconductor region 20 in the base portion 20z and the protrusions 20a and 20b may be formed by ion implantation with the same mask. In this case, the impurity concentrations of the base portion 20z and the protrusions 20a and 20b are the same.

Next, the basic operation of the photoelectric conversion apparatus according to this embodiment is described with reference to FIG. 1 and FIG. 2.

First, the reset MOS transistor 12 is driven with the reset signal φR, and the anode of the photodiode 11 is reset to a voltage corresponding to the reset voltage Vres. In this case, the reset voltage Vres is set so that a potential (Vres-Vth) to be applied to the anode of the photodiode 11 becomes a reverse voltage sufficient for completely depleting the P⁺-type semiconductor region 20. Note that, Vth refers to a threshold voltage of the reset MOS transistor 12.

When the reverse voltage continues to be applied to the anode (electrode 22) of the photodiode 11, a depletion layer between the P⁺-type semiconductor region 20 and the N⁻-type semiconductor region 23 and a depletion layer between the P⁺-type semiconductor region 20 and the N⁺⁺-type semiconductor region 24 spread gradually. Then, those depletion layers are connected to each other at a predetermined reverse voltage, with the result that the P⁺-type semiconductor region 20 interposed between those depletion layers is completely depleted. The voltage at this time is referred to as a depletion voltage of the P⁺-type semiconductor region 20. Note that, even when the reverse voltage continues to be applied further, the potential of the P⁺-type semiconductor region 20 does not change. The value of the reset voltage Vres is set so that a voltage exceeding the depletion voltage is applied to the anode of the photodiode 11.

Next, the reset MOS transistor 12 is turned off with the reset signal φR, to thereby complete reset processing of the photodiode 11. An accumulation period of a signal charge in the photodiode 11 starts from this initial state, and a signal charge corresponding to the amount of incident light is generated through photoelectric conversion in the photodiode 11. The generated signal charge is attracted to the P⁺-type semiconductor region 20 having the potential reset with the potential (Vres-Vth). With this, the amplification MOS transistor 13 is put into a state in which the voltage corresponding to the amount of the signal charge generated by the photodiode 11 is applied to the gate.

When the select MOS transistor 14 is driven with the select signal φS under this state, the amplification MOS transistor 13 is put into a source follower state in which the drain is grounded and a bias current is supplied to the source from the constant current source 15 through the select MOS transistor 14. With this, a gate voltage of the amplification MOS transistor 13, that is, an output signal of the amplification MOS transistor 13 corresponding to the amount of the signal charge generated by the photodiode 11 is output to the signal read line 16 through the select MOS transistor 14. Then, the output signal output to the signal read line 16 is output as a pixel signal through the output buffer 17. In the case where the plurality of unit pixels 10 are arranged, pixel signals can be output sequentially from the unit pixels 10 by shifting drive timing of the select MOS transistors 14 of the plurality of unit pixels 10.

Next, the process of generation and accumulation of a signal charge in the photodiode 11 of the photoelectric conversion apparatus according to this embodiment is described more specifically.

As described above, the photodiode 11 serving as the photoelectric conversion element is formed of the PN junction between the P⁺-type semiconductor region 20 having the base portion 20z and the protrusions 20a and 20b and the N⁻-type semiconductor region 23. The signal charge (hole in this case) generated through photoelectric conversion in the photodiode 11 is collected and accumulated in the P⁺-type semiconductor region 20. That is, the P⁺-type semiconductor region 20 corresponds to an accumulation region of a signal charge. The P⁺-type semiconductor region 20 is put into a depletion state when a reset potential is applied through the electrode 22 and the P⁺⁺-type semiconductor region 28 and serves to accumulate a charge while suppressing an increase in capacitance. Note that, when the reset voltage is applied to the electrode 22, the N⁻-type semiconductor region 23 is not completely put into a depletion state but includes a neutral region (region that is not depleted).

A charge generated in the N⁻-type semiconductor region 23 positioned in a region separate from the P⁺-type semiconductor region 20 in plan view moves to the P⁺-type semiconductor region 20 through the N⁻-type semiconductor region 23 in a horizontal direction (direction parallel to the surface of the semiconductor substrate 30) and then is accumulated in the P⁺-type semiconductor region 20.

FIG. 2(c) is a potential distribution along the line B-B′ of FIG. 2(b) when the reset voltage is applied to the electrode 22. The potential along the line B-B′ is roughly classified into three regions: a potential region having a distance L0 in the P⁺⁺-type semiconductor region 28, a potential region having the distance L2 from an end portion of the P⁺⁺-type semiconductor region 28 to the base portion 20z, and a potential region having the distance L1 in the protrusion 20a. The potential of the potential region having the distance L0 in the P⁺⁺-type semiconductor region 28 is (Vres-Vth). Line segments indicating those distances illustrated in FIG. 2(b) and FIG. 2(c) are hereinafter referred to as “line segment L0”, “line segment L1”, “line segment L2”, and the like.

The base portion 20z is subjected to pinning with the above-mentioned voltage that completely puts the P⁺-type semiconductor region 20 into a depletion state, that is, the depletion voltage. Thus, as illustrated in FIG. 2(c), the potential of the potential region having the distance L1 related to the protrusion 20a is a value between the potential of the P⁺⁺-type semiconductor region 28 and the potential of the N⁺⁺-type semiconductor region 25, which changes continuously depending on the position.

Herein, the potential in the N⁻-type semiconductor region 23 is substantially constant in a pixel structure having a certain area or more, and a potential difference P corresponding to the difference between N-type impurity concentrations is generated in a portion in contact with the N⁺⁺-type semiconductor region 25. The N⁺⁺-type semiconductor region 25 prevents a signal charge in the N⁻-type semiconductor region 23 from flowing out to an adjacent element region. It is desired that the potential height of the N⁺⁺-type semiconductor region 25 with respect to the N⁻-type semiconductor region 23 be a value which thermal energy cannot exceed, for example, about 0.25 V or more. When the impurity concentration of the N⁺⁺-type semiconductor region 25 is set to be higher than that of the N⁻-type semiconductor region 23 by at least about four orders of magnitude, a potential barrier (potential difference P) of 0.25 V or more, which can sufficiently prevent a signal charge from flowing out to an adjacent pixel, can be obtained. Note that, the same also applies to the N⁺⁺-type semiconductor region 26 arranged under the N⁻-type semiconductor region 23. The outflow of a charge generated in the N⁻-type semiconductor region 23 to an adjacent pixel or a substrate is suppressed by the N⁺⁺-type semiconductor regions 25 and 26, and the charge moves to the P⁺-type semiconductor region 20 while diffusing.

The potentials on the line segment L1 and the line segment L2 are described in more detail. The potential on the line segment L1 changes depending on the condition, such as the dimension of the PN junction formed by the P⁺-type semiconductor region 20, the N⁻type semiconductor region 23, and the N⁺⁺-type semiconductor region 24. Further, the potential on the line segment L1 changes also depending on the width of the protrusion 20a, that is, the length of the protrusion 20a in a direction perpendicular to the line A-A′ at each point of the line segment L1. The potential change is caused by the following: the width of the protrusion 20a is smaller than that of the base portion 20z, and hence the effect of substantially decreasing the impurity concentration of the P⁺-type semiconductor region 20 occurs. Further, the potential change is caused also by the influence of the depletion layer extending from the N⁻-type semiconductor region 23. For those reasons, the potential on the B-B′ line changes in the protrusion 20a having the width that changes along the line segment L1. Due to the potential change, an electric field is generated from the apex of the protrusion 20a to the base portion 20z.

For example, it is assumed that the impurity concentration of the N⁻-type semiconductor region 23 is 1×10¹⁴ [cm⁻³], the impurity concentration of the N⁺⁺-type semiconductor region 24 is 1×10¹⁷ [cm⁻³], and the impurity concentration of the P⁺-type semiconductor region 20 is 2×10¹⁶ [cm⁻³]. In this case, the above-mentioned potential change on the line segment L1 in accordance with the width occurs within a range of the width of the protrusion 20a of about 4 μm or less. Thus, in order to generate an electric field directed from the apex of the protrusion 20a to the base portion 20z in the entire region on the line segment L1 of the protrusion 20a, it is preferred that the width of the protrusion 20a be set to change continuously from the apex to the bottom side within a range of from 0 μm to 4 μm. Specifically, it is preferred that the shape of the protrusion 20a be a triangle having a bottom side with a length of 4 μm or less.

The potential along the line segment L2 of the base portion 20z is substantially constant, and the potential (Vres-Vth) is applied in the vicinity of the P⁺⁺-type semiconductor region 28. Therefore, the potential on the line segment L2 becomes a value close to the potential (Vres-Vth). In other words, as is understood from FIG. 2(c), the potential gradient in the protrusion 20a is larger than that on the line segment L2 of the base portion 20z. A charge generated in the base portion 20z and a charge having reached the base portion 20z from the protrusion 20a mainly move while diffusing in the region having a substantially constant potential, and is moved by a drift upon reaching the vicinity of the P⁺⁺-type semiconductor region 28.

FIG. 3(a) is a view obtained by rotating FIG. 2(a) by 90°. The same portions as those of FIG. 2(a) are denoted by the same reference symbols as those therein. FIG. 3(b) is a sectional view taken along the line D-D′ of FIG. 3(a). The line D-D′ is a line segment passing through the apexes of the protrusions 20b. FIG. 3(c) is a view for illustrating a potential distribution along the line E-E′ of FIG. 3(b). The potential along the line E-E′ is roughly classified into three regions: a potential region having the distance L0 in the P⁺⁺-type semiconductor region 28, a potential region having the distance L4 from the end portion of the P⁺⁺-type semiconductor region 28 to the base portion 20z, and the potential region having the distance L3 in the protrusion 20b. The potential of the potential region having the distance L0 in the P⁺⁺-type semiconductor region 28 is (Vres-Vth).

In the same way as in the potential on the line segment L1, the potential on the line segment L3 changes depending on the condition, such as the dimension of the PN junction formed by the P⁺-type semiconductor region 20, the N⁻-type semiconductor region 23, and the N⁺⁺-type semiconductor region 24. Further, the potential on the line segment L3 changes also depending on the width of the protrusion 20b, that is, the length of the protrusion 20b in a direction perpendicular to the line D-D′ at each point of the line segment L3.

Further, in the same way as in the potential on the line segment L2, the potential on the line segment L4 becomes a value close to (Vres-Vth). In other words, as is understood from FIG. 3(c), the potential gradient in the protrusion 20b is larger than that on the line segment L4 of the base portion 20z. A charge generated in the base portion 20z and a charge having reached the base portion 20z from the protrusion 20b mainly move while diffusing in the region having a substantially constant potential, and is moved by a drift upon reaching the vicinity of the P⁺⁺-type semiconductor region 28.

Next, the relationship between the axial length L1 of the protrusion 20a and the axial length L3 of the protrusion 20b, and the relationship between the distance L2 and the distance L4, which are distances from the outer periphery of the base portion 20z to the P⁺⁺-type semiconductor region 28, are described. In this embodiment, the axial length L1 is set to be larger than the axial length L3, and the distance L2 is set to be smaller than the distance L4. That is, the shapes of the protrusions 20a and 20b and the base portion 20z are set so as to satisfy the relationships of (L1>L3) and (L2<L4). Note that, the size relation of the axial lengths of the protrusion 20a and the protrusion 20b may be reversed. In this case, the relationship between the distance L2 and the distance L4 is also reversed. Specifically, in this case, the axial length L3 is set to be larger than the axial length L1, and the distance L2 is set to be larger than the distance L4. That is, the shapes of the protrusions 20a and 20b and the base portion 20z are set so as to satisfy the relationships of (L1<L3) and (L2>L4).

Next, the reason for forming the protrusions 20a and 20b and the base portion 20z into the above-mentioned shapes is described.

As described above, when depletion occurs, a potential gradient directed to the base portion 20z is generated in the protrusions 20a and 20b. When light is radiated to the photodiode 11 under this state, a large part of the charge generated in the N⁻-type semiconductor region 23 moves while diffusing to the P⁺-type semiconductor region 20 in the vicinity of a charge generation portion. The charge collected into the protrusions 20a and 20b moves to the base portion 20z through the potential gradient.

In the movement of the charge, as the axial lengths of the protrusions 20a and 20b increase, the collection charge amount also increases. Therefore, for example, in the case where the distance L2 is set to be the same as the distance L4, the inflow charge amount is larger in the protrusion having a larger axial length, and hence it takes time for collecting the charge into the P⁺⁺-type semiconductor region 28. When an image is taken by using such photoelectric conversion apparatus, a residual image is generated in some cases, which may become the factor of degrading image quality.

In the photoelectric conversion apparatus according to this embodiment, in the case where the axial length L1 of the protrusion 20a is larger than the axial length L3 of the protrusion 20b, the distance L2 is set to be smaller than the distance L4. With this, the time required for the movement of the charge collected in the protrusion 20a having a larger axial length is shortened. Meanwhile, in the protrusion 20b having a shorter axial length, the movement of the charge to the base portion 20z ends within a short period of time due to the shorter axial length, and hence there is less influence even when the distance L2 is set to be larger.

For the reason described above, in the photoelectric conversion apparatus according to this embodiment, the charge collection speed is increased, and the generation of a residual image at time of photographing may be reduced.

In the photoelectric conversion apparatus according to this embodiment, the base portion 20z is in a depletion state. The potential in this region is subjected to pinning with the depletion voltage, and hence a charge is transported in the base portion 20z mainly through diffusion rather than a drift caused by an electric field. Therefore, the influence caused by setting the distance L4 to be larger than the distance L2 becomes outstanding. Specifically, the configuration of this embodiment is more useful compared to the case where a charge is transported mainly through diffusion in the base portion 20z.

Further, the configuration of this embodiment is more useful in a solid-state imaging apparatus including pixels each having a large area of 10 μm or more per side, in which the transport distance of a signal charge in the photodiode 11 is relatively large, and the charge movement is liable to be delayed.

Note that, the inventors of the present invention have confirmed that a photoelectric conversion apparatus having an increased charge collection speed can be obtained by setting a parameter of each portion of the photodiode 11, based on the above-mentioned contents according to this embodiment.

Thus, according to this embodiment, a photoelectric conversion apparatus having an increased charge collection speed is provided, and a residual image at time of photographing can be reduced.

### Second Embodiment

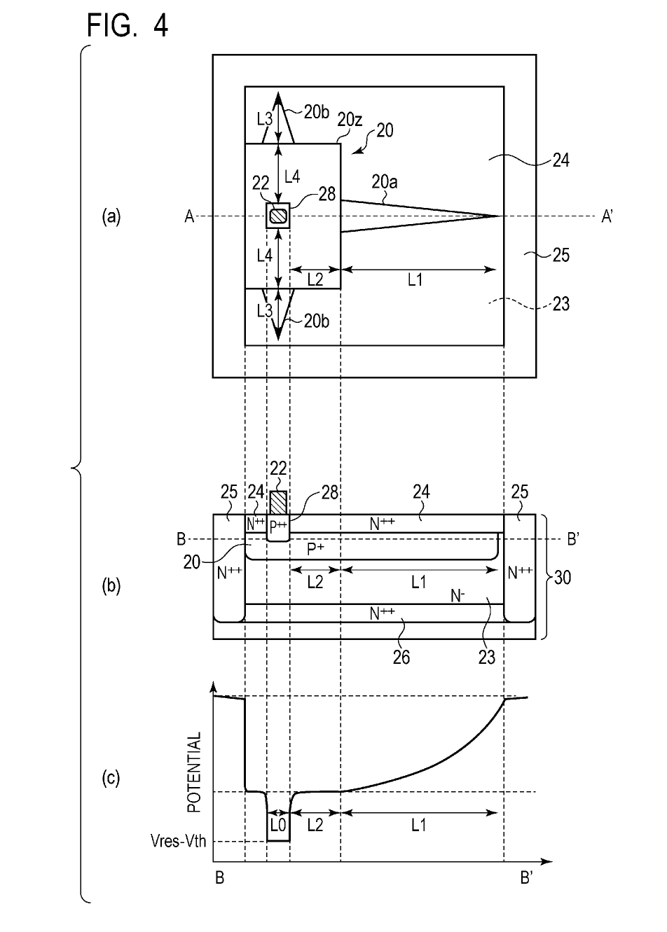

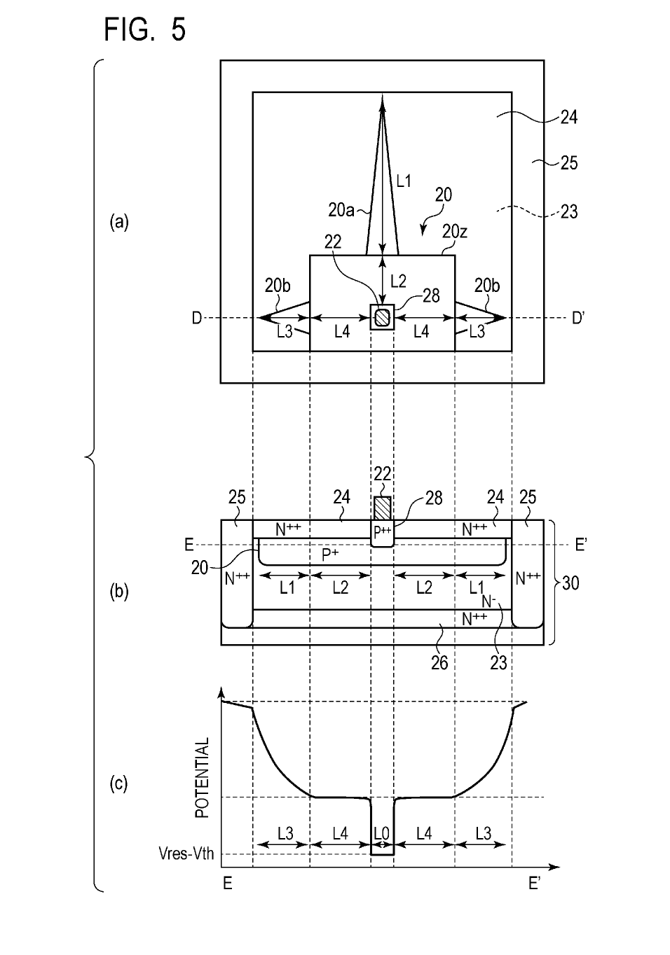

A photoelectric conversion apparatus according to a second embodiment of the present invention is described with reference to FIG. 4 and FIG. 5. Note that, in FIG. 4 and FIG. 5, the same components as those of the photoelectric conversion apparatus according to the first embodiment illustrated in FIG. 1 to FIG. 3 are denoted by the same reference symbols as those therein, and the descriptions thereof are omitted or simplified.

A read circuit and a reset circuit of the photoelectric conversion apparatus according to this embodiment are the same as those according to the first embodiment, and hence the descriptions thereof are omitted. FIG. 4(a) is a plan view for illustrating a planar layout of the photodiode 11. FIG. 4(b) is a sectional view taken along the line A-A′ of FIG. 4(a). FIG. 4(c) is a view for illustrating a potential distribution of a portion along the line B-B′ of FIG. 4(b).

FIG. 5(a) is a view obtained by rotating FIG. 4(a) by 90°. The same portions as those of FIG. 4(a) are denoted by the same reference symbols therein. FIG. 5(b) is a sectional view taken along the line D-D′ of FIG. 5(a). The line D-D′ is a line segment passing through the apexes of the protrusions 20b. FIG. 5(c) is a view for illustrating a potential distribution along the line E-E′ of FIG. 5(b).

In the second embodiment, unlike the first embodiment, one side of the base portion 20z is arranged along the N⁺⁺-type semiconductor region 25 formed in an outer peripheral portion of the photodiode 11. That is, the base portion 20z is close to an outer peripheral side of the photodiode 11. Along with the configuration change, the number of the protrusions 20a is reduced from two to one.

As illustrated in FIG. 1, pixel circuit elements, such as the reset MOS transistor 12 and the amplification MOS transistor 13 forming the unit pixel 10, are connected to the photodiode 11. Therefore, in an actual element layout, those pixel circuit elements are also arranged around the photodiode 11. The pixel circuit elements are connected to the electrode 22 of the photodiode 11 through wiring made of a metal or the like.

A voltage applied to a gate node of the amplification MOS transistor 13 in accordance with the charge generated in the photodiode 11 increases as the electrostatic capacitance of the gate node of the amplification MOS transistor 13 decreases. The electrostatic capacitance includes a PN-junction capacitance formed in the photodiode 11, a wiring capacitance between the photodiode 11 and the gate of the amplification MOS transistor 13, and a wiring capacitance between the photodiode 11 and the source of the reset MOS transistor 12.

In this embodiment, one side of the base portion 20z is close to the outer peripheral side of the photodiode 11, and hence the base portion 20z and the electrode 22 can be arranged at positions closer to the pixel circuit elements. With this, the wiring between the photodiode 11 and the gate of the amplification MOS transistor 13 and the wiring between the photodiode 11 and the source of the reset MOS transistor 12 can be shortened compared to the configuration of the first embodiment. Thus, capacitances generated by those wirings are reduced, and the electrostatic capacitance of the gate node of the amplification MOS transistor 13 is also reduced. Therefore, the voltage to be input to the gate node of the amplification MOS transistor 13, which corresponds to the amount of a generated charge, increases, and the sensitivity of the photoelectric conversion apparatus is further improved.

In addition to the effect of the first embodiment, as described above, the photoelectric conversion apparatus according to this embodiment further has the effect in which the voltage to be input to the gate node of the amplification MOS transistor 13, which corresponds to the amount of a generated charge, increases to improve the sensitivity of the photoelectric conversion apparatus.

### Modified Example of Second Embodiment

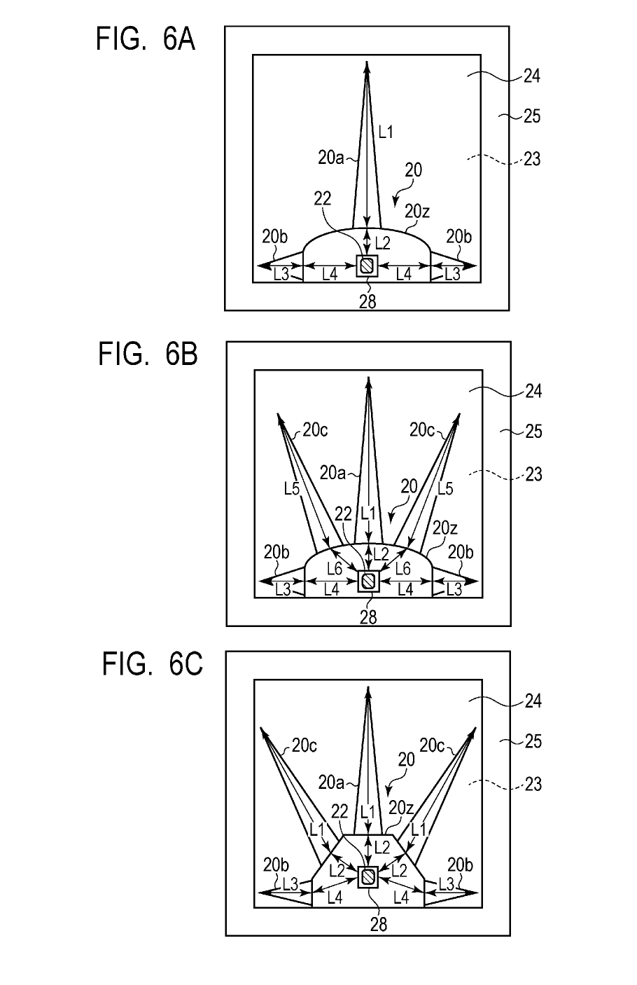

FIG. 6A, FIG. 6B, and FIG. 6C are each a view for illustrating a planar layout of a photodiode in a photoelectric conversion apparatus according to a modified example of the second embodiment. Each figure is obtained by modifying the shape of the P⁺-type semiconductor region 20 illustrated in FIG. 5(a), and the configuration of each portion other than the P⁺-type semiconductor region 20 is the same as that of the second embodiment described above.

FIG. 6A is a view for illustrating a modified example in which corners of the base portion 20z are curved. As illustrated in FIG. 6A, the shape of the base portion 20z may be different from the rectangle described in the first embodiment or the second embodiment. Besides the above-mentioned shape, the shape of the base portion 20z may be, for example, a polygon or a shape including an arc. Those shapes may be combined appropriately.

FIG. 6B is a view for illustrating a modified example further including two protrusions 20c (third protrusions) in addition to one protrusion 20a and two protrusions 20b. The shape of the base portion 20z is the same as that of the modified example of FIG. 6A. A bottom side of the protrusion 20c is positioned between the bottom side of the protrusion 20a and the bottom side of the protrusion 20b. Further, the angle of an axis of the protrusion 20c is set to be an angle between the axis of the protrusion 20a and the axis of the protrusion 20b that are formed at a perpendicular angle. The axial length of the protrusion 20c is L5, and the distance from the bottom side of the protrusion 20c to the P⁺⁺-type semiconductor region 28 is L6.

In this modified example, the axial length L5 is set to be larger than the axial length L3 and is set to be smaller than the axial length L1. Meanwhile, the distance L6 is set to be larger than the distance L2 and is set to be smaller than the distance L4. That is, the shapes of the protrusions 20a, 20b, and 20c, and the base portion 20z are set so as to satisfy the relationships of (L1>L5>L3) and (L2<L6<L4). Note that, as described in the first embodiment, the size relation of the axial length L1 and the axial length L3 may be reversed, and in this case, the shapes of the protrusions 20a, 20b, and 20c and the base portion 20z are set so as to satisfy the relationships of (L1<L5<L3) and (L2>L6>L4).

FIG. 6C is a view for illustrating a modified example in which the axial length and the distance from the bottom side to the P⁺⁺-type semiconductor region 28 of the protrusion 20c of FIG. 6B are set to be the same as those of the protrusion 20a. In other words, in this modified example, the number of the protrusions 20a is increased from one to three. In this modified example, in the same way as in the first embodiment, the shapes of the protrusions 20a, 20b, and 20c, and the base portion 20z are set so as to satisfy the relationships of (L1>L3) and (L2<L4). Note that, the configuration of FIG. 6C can be considered as follows: the shapes of the protrusions 20a, 20b, and 20c, and the base portion 20z are set so as to satisfy the relationships of (L1=L5>L3) and (L2=L6<L4) in the configuration of FIG. 6B.

The foregoing is summarized as follows. The shapes of the protrusions 20a, 20b, and 20c, and the base portion 20z according to the modified examples of FIG. 6B and FIG. 6C are set so as to satisfy the relationships of (L1≧L5>L3) and (L2≦L6<L4) or the relationships of (L1≦L5<L3) and (L2≧L6>L4).

In the modified examples illustrated in FIG. 6B and FIG. 6C, the protrusions are arranged also at an angle other than the horizontal direction and the vertical direction. The present invention can also be applied to such configuration by setting the shapes of the protrusions and the base portion as described above.

In the case where the amount of a generated charge increases under the photographing condition in which the amount of light entering the photodiode 11 is large, the potential of the base portion 20z may increase due to a large amount of charges having moved to the base portion 20z. This is because, when the charge concentration of the base portion 20z becomes high, the potential increase due to self-induction. In the case where the number of the protrusions is large, and the bottom sides of the protrusions are concentrated on the base portion 20z as in the modified examples of FIG. 6B and FIG. 6C, the potential of the base portion 20z increases owing to the above-mentioned factor, and hence the movement of a charge from the protrusions becomes slow, which may limit the charge collection speed. With this, the generation of a residual image may become more conspicuous. Therefore, in the modified examples illustrated in FIG. 6B and FIG. 6C, the effects of the present invention may be attained more remarkably.

### Third Embodiment

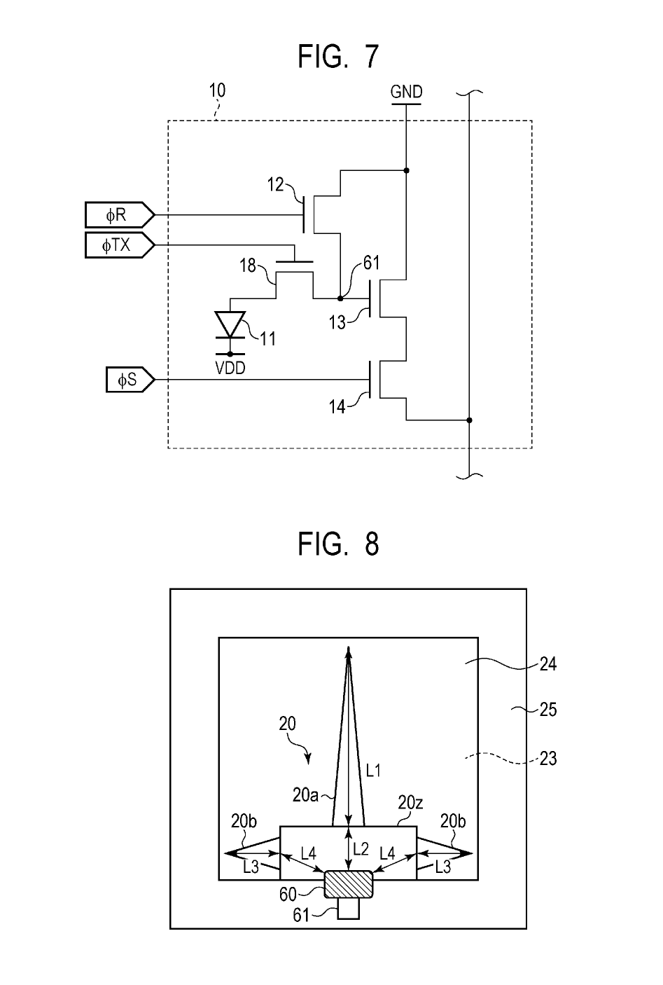

A photoelectric conversion apparatus according to a third embodiment of the present invention is described with reference to FIG. 7 and FIG. 8. FIG. 7 is a circuit diagram for illustrating a read circuit and a reset circuit of the photoelectric conversion apparatus according to this embodiment. FIG. 8 is a view for illustrating a planar layout of a photodiode in the photoelectric conversion apparatus according to this embodiment. The same components as those of the photoelectric conversion apparatus according to the first embodiment and the second embodiment illustrated in FIG. 1 to FIG. 5, FIG. 6A, FIG. 6B, and FIG. 6C are denoted by the same reference symbols as those therein, and the descriptions thereof are omitted or simplified.

As illustrated in FIG. 7, the pixel of the photoelectric conversion apparatus according to this embodiment further includes a transfer MOS transistor 18 between the anode of the photodiode 11 and a connection node between the source of the reset MOS transistor 12 and the gate of the amplification MOS transistor 13. This pixel is not a so-called direct connection-type pixel described in the first embodiment but a transfer-type pixel.

A source of the transfer MOS transistor 18 is connected to the anode of the photodiode 11, and a drain thereof is connected to the connection node between the source of the reset MOS transistor 12 and the gate of the amplification MOS transistor 13. The gate of the transfer MOS transistor 18 is connected to a transfer gate signal line (not illustrated) so that the operation of the transfer MOS transistor 18 can be controlled with a select signal φTX. A connection node of the source of the reset MOS transistor 12, the gate of the amplification MOS transistor 13, and the drain of the transfer MOS transistor 18 forms a P⁺⁺-type floating diffusion region 61.

When the transfer MOS transistor 18 is operated at desired timing, a charge accumulated in the photodiode can be read concurrently to a gate side of the amplification MOS transistor 13. A pixel signal in a reset state and a pixel signal after the signal charge is transferred concurrently are read separately, and a difference between outputs thereof is taken, to thereby remove a noise component in the in-pixel read circuit after the transfer MOS transistor 18.

Next, the specific configuration of the photodiode 11 in the photoelectric conversion apparatus according to this embodiment is described with reference to FIG. 8. FIG. 8 is a plan view for illustrating a planar layout of the photodiode 11. The sectional structure and potential distribution of this embodiment are the same as those of the second embodiment and hence are not illustrated.

The third embodiment is different from the first embodiment and the second embodiment in that a gate electrode 60 of the transfer MOS transistor 18 is arranged in place of the P⁺⁺-type semiconductor region 28 and the electrode 22, and the base portion 20z is connected to the P⁺⁺-type floating diffusion region 61 through intermediation of the transfer MOS transistor 18. The P⁺⁺-type floating diffusion region 61 is connected to the gate of the amplification MOS transistor 13. When the transfer MOS transistor 18 is turned on, a charge accumulated in the photodiode 11 is transferred to the P⁺⁺-type floating diffusion region 61, and a voltage corresponding to the charge is output to the drain of the amplification MOS transistor 13.

Note that, the distance from the bottom side of the protrusion to the electrode 22 defined in the first embodiment and the second embodiment corresponds to a shortest distance from the bottom side of the protrusion to the gate electrode 60 of the transfer MOS transistor 18 in the third embodiment. Further, the size relation of L1, L2, L3, and L4 in the third embodiment is the same as that in the first embodiment and the second embodiment.

As described above, according to this embodiment, in addition to the effect of the first embodiment or the second embodiment, an output signal having less noise can be obtained through the addition of the transfer MOS transistor to the in-pixel read circuit.

### Fourth Embodiment

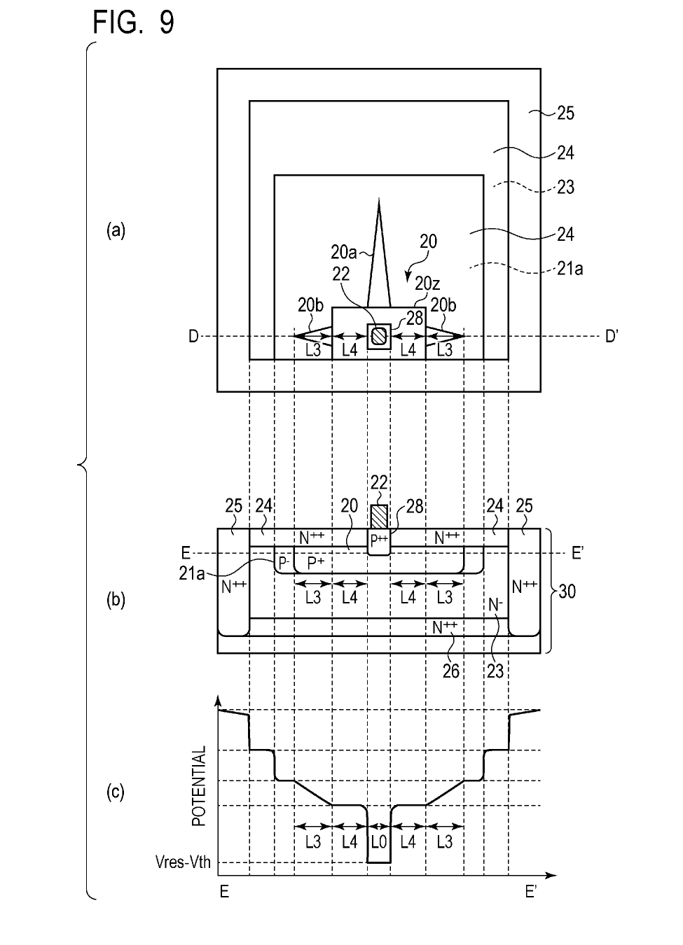

A photoelectric conversion apparatus according to a fourth embodiment of the present invention is described with reference to FIG. 9. The same components as those of the photoelectric conversion apparatus according to the first embodiment to the third embodiment illustrated in FIG. 1 to FIG. 8 are denoted by the same reference symbols as those therein, and the descriptions thereof are omitted or simplified. FIG. 9(a) is a plan view for illustrating a planar layout of the photodiode 11. FIG. 9(b) is a sectional view taken along the line D-D′ of FIG. 9(a). FIG. 9(c) is a view for illustrating a potential distribution of a portion along the line E-E′ of FIG. 9(b).

The photoelectric conversion apparatus according to this embodiment is different from those of the first embodiment to the third embodiment in that a P⁻-type semiconductor region 21a (fourth semiconductor region) is further formed. The P⁻-type semiconductor region 21a is formed between the P⁺-type semiconductor region 20 and the N⁻-type semiconductor region 23 in plan view. The P⁻-type semiconductor region 21a is formed of a P⁻-type semiconductor region having a concentration lower than that of the P⁺-type semiconductor region 20. With such structure, a potential difference caused by a PN junction is formed at a boundary between the N⁻-type semiconductor region 23 and the P⁻-type semiconductor region 21a. The electric field generated in the vicinity of the potential difference facilitates the movement of a charge generated in the N⁻-type semiconductor region 23 to the P⁻-type semiconductor region 21a. As a result, the charge collection speed can be further increased. Thus, according to this embodiment, a photoelectric conversion apparatus having an increased charge collection speed is provided, and a residual image at time of photographing can be reduced.

Note that, in this embodiment, the potential difference between the N⁻-type semiconductor region 23 and the P⁻-type semiconductor region 21a is realized by the PN junction. That is, the N⁻-type semiconductor region 23 and the P⁻-type semiconductor region 21a have different conductivity types. However, the N⁻-type semiconductor region 23 and the P⁻-type semiconductor region 21a may have the same conductivity type with different impurity concentrations. In this case, a potential difference is also formed through an impurity concentration difference.

### Fifth Embodiment

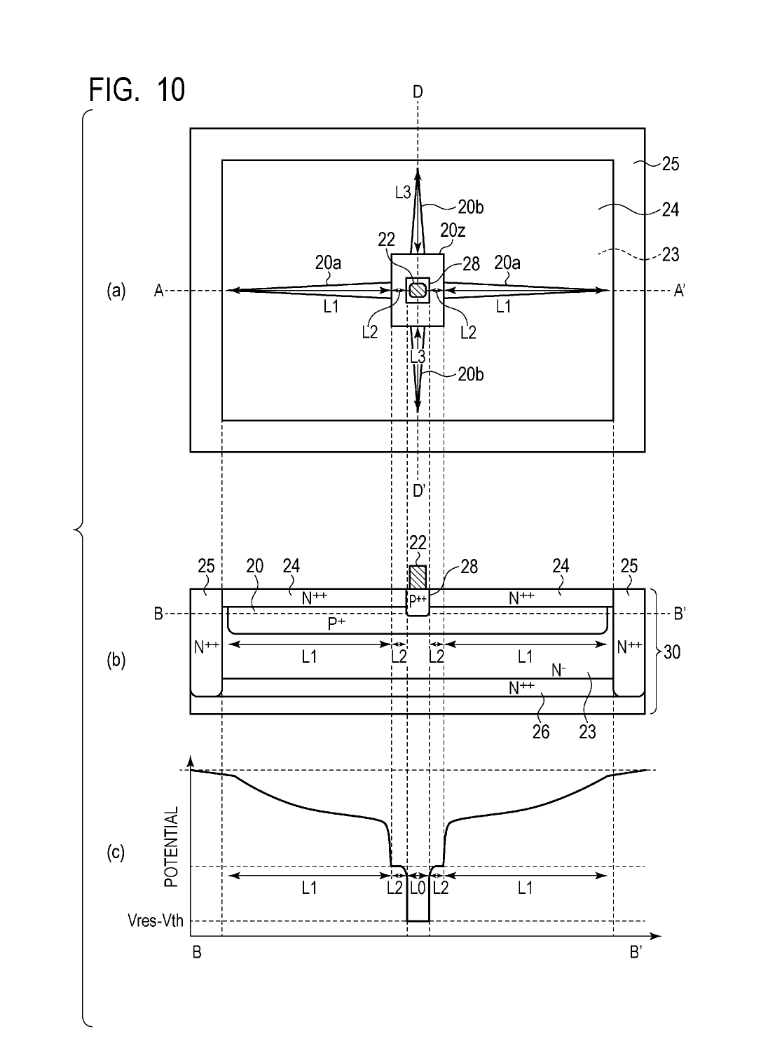

A photoelectric conversion apparatus according to a fifth embodiment of the present invention is described with reference to FIG. 10. The same components as those of the photoelectric conversion apparatus according to the first embodiment to the fourth embodiment illustrated in FIG. 1 to FIG. 9 are denoted by the same reference symbols as those therein, and the descriptions thereof are omitted or simplified. FIG. 10(a) is a plan view for illustrating a planar layout of the photodiode 11. FIG. 10(b) is a sectional view taken along the line A-A′ of FIG. 10(a). FIG. 10(c) is a view for illustrating a potential distribution of a portion along the line B-B′ of FIG. 10(b).

In this embodiment, the protrusions 20a and 20b are formed more thinly than those of the first embodiment. With this, the potential on the line B-B′ has a difference in level at a boundary between the protrusion 20a and the base portion 20z. The reason for the generation of the potential difference is that the width of the P⁺-type semiconductor region 20 suddenly becomes large at the boundary between the protrusion 20a and the base portion 20z.

With such configuration, the transport time of a charge from the protrusion 20a to the base portion 20z becomes shorter by virtue of the electric field generated in the vicinity of the potential difference. Thus, according to this embodiment, a photoelectric conversion apparatus having an increased charge collection speed is provided, and a residual image at time of photographing can be further reduced.

### Sixth Embodiment

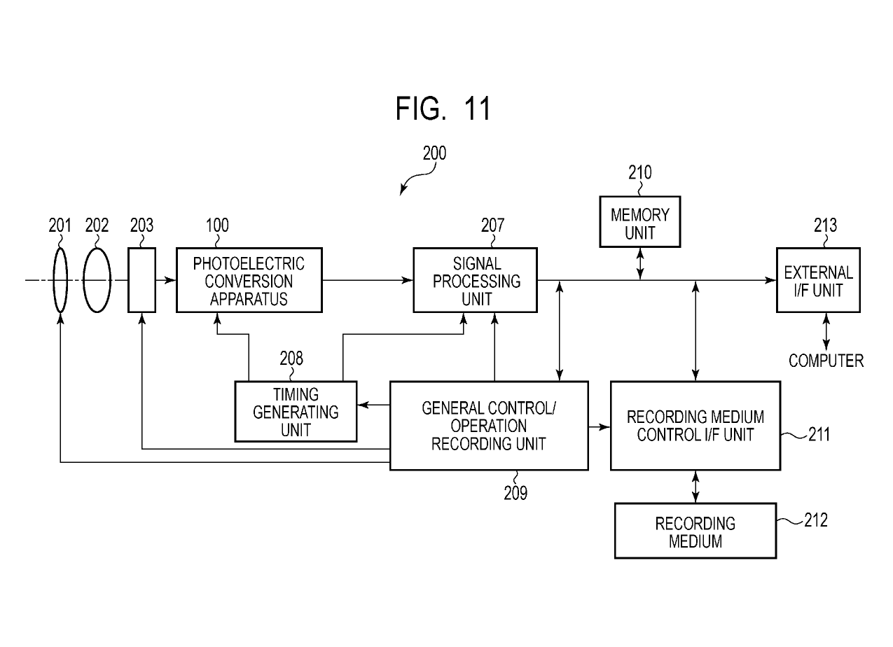

An imaging system according to a sixth embodiment of the present invention is described with reference to FIG. 11. FIG. 11 is a schematic diagram for illustrating a configuration of the imaging system according to this embodiment.

An imaging system 200 according to this embodiment, which is not particularly limited, can be applied to, for example, a digital still camera, a digital camcorder, a camera head, a copying machine, a facsimile machine, a mobile phone, an in-vehicle camera, and an observation satellite.

The imaging system 200 includes a photoelectric conversion apparatus 100, a lens 202, a diaphragm 203, a barrier 201, a signal processing unit 207, a timing generating unit 208, a general control/operation unit 209, a memory unit 210, a recording medium control I/F unit 211, and an external I/F unit 213.

The lens 202 is configured to form an optical image of a subject in the photoelectric conversion apparatus 100. The diaphragm 203 is configured to make the amount of light passing through the lens 202 variable. The barrier 201 is configured to protect the lens 202. The photoelectric conversion apparatus 100 is the photoelectric conversion apparatus described in the above-mentioned embodiments and is configured to convert the optical image formed by the lens 202 into image data.

The signal processing unit 207 is a signal processing unit configured to perform processing of subjecting the image data output from the photoelectric conversion apparatus 100 to various corrections and compression. An AD converter for subjecting the image data to AD conversion may be mounted on the same substrate as that of the photoelectric conversion apparatus 100 or may be mounted on a separate substrate. Further, the signal processing unit 207 may also be mounted on the same substrate as that of the photoelectric conversion apparatus 100 or may be mounted on a separate substrate. The timing generating unit 208 is configured to output various timing signals to the photoelectric conversion apparatus 100 and the signal processing unit 207. The general control/operation unit 209 is a general control unit configured to control the entire imaging system 200. In this case, a timing signal and the like may be input from outside of the imaging system 200, and it is sufficient that the imaging system 200 include at least the photoelectric conversion apparatus 100 and the signal processing unit 207 configured to process the imaging signal output from the photoelectric conversion apparatus 100.

The memory unit 210 is a frame memory unit for temporarily storing image data. The recording medium control I/F unit 211 is an interface unit for recording data onto the recording medium 212 or reading data therefrom. The recording medium 212 is a detachable recording medium, such as a semiconductor memory, for recording or reading image data. The external I/F unit 213 is an interface unit for communicating to/from an external computer and the like.

An image of good quality with a residual image reduced can be obtained by configuring an imaging system employing the photoelectric conversion apparatus according to the first embodiment to the fifth embodiment as described above.

### Modified Embodiments

The present invention can be modified variously without being limited to the above-mentioned embodiments.

For example, in each of the second embodiment to the fifth embodiment, an example in which the photoelectric conversion apparatus according to the first embodiment is modified or an example in which additional configurations are added is described. However, two or more of the configurations described in the first embodiment to the fifth embodiment may be appropriately selected to be combined.

The imaging system described in the sixth embodiment exemplifies an imaging system to which the photoelectric conversion apparatus according to the present invention is applicable, and the imaging system to which the photoelectric conversion apparatus according to the present invention is applicable is not limited to the configuration illustrated in FIG. 11.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2015-030289, filed Feb. 19, 2015, which is hereby incorporated by reference herein in its entirety.

What is claimed is:

1. A photoelectric conversion apparatus, comprising:
a photoelectric conversion element including:
a first semiconductor region of a first conductivity type formed in a semiconductor substrate;
a second semiconductor region of a second conductivity type formed in the semiconductor substrate, the first semiconductor region and the second semiconductor region forming a PN junction; and
a third semiconductor region of a second conductivity type formed in contact with a surface of the semiconductor substrate and in contact with the second semiconductor region; and
a read circuit electrically connected to the third semiconductor region, the read circuit being configured to read a charge generated by the photoelectric conversion element,
wherein the second semiconductor region has a shape in plan view including:
a base portion containing the third semiconductor region in the plan view; and
a first protrusion and a second protrusion, each being connected to the base portion and having a width that becomes small from a side connected to the base portion toward a tip end, and
wherein, when a first distance from the tip end of the first protrusion to a connected portion between the first protrusion and the base portion in the plan view is defined as L1,
a second distance from the connected portion between the first protrusion and the base portion to the third semiconductor region in the plan view is defined as L2,
a third distance from the tip end of the second protrusion to a connected portion between the second protrusion and the base portion in the plan view is defined as L3, and
a fourth distance from the connected portion between the second protrusion and the base portion to the third semiconductor region in the plan view is defined as L4,
relationships of L1>L3 and L2<L4 are satisfied.

2. The photoelectric conversion apparatus according to claim 1, wherein, in the connected portion between one of the first protrusion and the second protrusion, and the base portion, the base portion has a width larger than the width of one of the first protrusion and the second protrusion.

3. The photoelectric conversion apparatus according to claim 1, wherein the base portion is formed along a barrier layer arranged in an outer peripheral portion of the photoelectric conversion element.

4. The photoelectric conversion apparatus according to claim 1,
wherein the second semiconductor region further includes a third protrusion connected to the base portion and having a width that becomes smaller from a side connected to the base portion toward a tip end, and
wherein, when a fifth distance from the tip end of the third protrusion to a connected portion between the third protrusion and the base portion is defined as L5, and
a sixth distance from the connected portion between the third protrusion and the base portion to the third semiconductor region is defined as L6,
relationships of L1≧L5>L3 and L2≦L6<L4 are satisfied.

5. The photoelectric conversion apparatus according to claim 1, wherein the read circuit comprises a transfer MOS transistor electrically connected to the third semiconductor region.

6. The photoelectric conversion apparatus according to claim 1, wherein the photoelectric conversion element further includes a fourth semiconductor region formed between the first semiconductor region and the second semiconductor region in the plan view, the first semiconductor region and the fourth semiconductor region being different in at least one of a conductivity type and an impurity concentration.

7. The photoelectric conversion apparatus according to claim 1, wherein the second semiconductor region has a potential difference formed by changing a width of the second semiconductor region.

8. The photoelectric conversion apparatus according to claim 1, wherein the first semiconductor region comprises a portion formed between the surface and the second semiconductor region.

9. The photoelectric conversion apparatus according to claim 1, wherein the first semiconductor region comprises a portion formed under the second semiconductor region.

10. The photoelectric conversion apparatus according to claim 1, wherein the first protrusion has a potential gradient larger than a potential gradient in the base portion from the connected portion between the first protrusion and the base portion to the third semiconductor region.

11. The photoelectric conversion apparatus according to claim 1, wherein the second protrusion has a potential gradient larger than a potential gradient in the base portion from the connected portion between the second protrusion and the base portion to the third semiconductor region.

12. An imaging system, comprising:
a photoelectric conversion apparatus including:
a photoelectric conversion element including:
a first semiconductor region of a first conductivity type formed in a semiconductor substrate;
a second semiconductor region of a second conductivity type formed in the semiconductor substrate, the first semiconductor region and the second semiconductor region forming a PN junction; and
a third semiconductor region of a second conductivity type formed in contact with a surface of the semiconductor substrate and in contact with the second semiconductor region; and
a read circuit electrically connected to the third semiconductor region, the read circuit being configured to read a charge generated by the photoelectric conversion element,
wherein the second semiconductor region has a shape in plan view including:
a base portion containing the third semiconductor region in the plan view; and
a first protrusion and a second protrusion, each being connected to the base portion and having a width that becomes small from a side connected to the base portion toward a tip end, and
wherein, when a first distance from the tip end of the first protrusion to a connected portion between the first protrusion and the base portion in the plan view is defined as L1,
a second distance from the connected portion between the first protrusion and the base portion to the third semiconductor region in the plan view is defined as L2,
a third distance from the tip end of the second protrusion to a connected portion between the second protrusion and the base portion in the plan view is defined as L3, and
a fourth distance from the connected portion between the second protrusion and the base portion to the third semiconductor region in the plan view is defined as L4,
relationships of L1>L3 and L2<L4 are satisfied; and
a signal processing unit configured to process a signal output from the photoelectric conversion apparatus.
